(19) United States
(12) Patent Application Publication
(10) Pub. No.: US 2026/0018384 A1
(43) Pub. Date: Jan. 15, 2026

(54) SHOWER PLATE AND SUBSTRATE PROCESSING APPARATUS

(71) Applicant: Tokyo Electron Limited, Tokyo (JP)

(72) Inventor: Kazuki HOSHI, Miyagi (JP)

(21) Appl. No.: 19/334,055

(22) Filed: Sep. 19, 2025

Related U.S. Application Data
(63) Continuation of application No. PCT/JP2024/012075, filed on Mar. 26, 2024.

(30) Foreign Application Priority Data
Apr. 3, 2023 (JP) 2023-060407

(51) Int. Cl. H01J 37/32

(52) U.S. Cl. CPC H01J 37/3244; H01J 37/32467; H01J 2237/002

(57) ABSTRACT

A shower plate includes a base that is an integrally formed body including a plurality of gas flow channels therein. Each of the plurality of gas flow channels includes a first portion extending in a thickness direction of the base, and a second portion communicating with the first portion and extending in a direction orthogonal to the thickness direction. Second portions belonging to different gas flow channels of the plurality of gas flow channels are arranged at mutually different positions in the thickness direction.

### CROSS-REFERENCE TO RELATED APPLICATION

This application is a continuation of International Application No. PCT/JP2024/012075, filed on Mar. 26, 2024 and designating the U.S., which claims priority to Japanese Patent Application No. 2023-060407, filed on Apr. 3, 2023. The contents of these applications are incorporated herein by reference in their entirety.

### TECHNICAL FIELD

The present disclosure relates to a shower plate and a substrate processing apparatus.

### BACKGROUND

US Patent Application Publication No. 2003/0124842 describes a showerhead provided in a substrate processing chamber and configured to supply two gases (for example, a titanium-containing compound gas and a nitrogen-containing compound gas) into a processing region.

### SUMMARY

According to one aspect of the present disclosure, a shower plate includes a base that is an integrally formed body including a plurality of gas flow channels therein. Each of the plurality of gas flow channels includes a first portion extending in a thickness direction of the base, and a second portion communicating with the first portion and extending in a direction orthogonal to the thickness direction. Second portions belonging to different gas flow channels of the plurality of gas flow channels are arranged at mutually different positions in the thickness direction.

### BRIEF DESCRIPTION OF THE DRAWINGS

FIG. 1 is an example of a diagram illustrating an example configuration of a capacitively coupled substrate processing apparatus;

FIG. 2 is an example of a schematic vertical cross-sectional view illustrating a configuration of a shower plate and an electrode plate according to an embodiment;

FIG. 3 is an example of a horizontal cross-sectional view of the shower plate at a pre-diffusion layer;

FIG. 4 is an example of a horizontal cross-sectional view of the shower plate at a first diffusion layer;

FIG. 5 is an example of a horizontal cross-sectional view of the shower plate at a second diffusion layer;

FIG. 6 is an example of a horizontal cross-sectional view of the shower plate at a third diffusion layer;

FIG. 7 is an example of a schematic view illustrating the arrangement of gas flow channels of the shower plate when the gas flow channels are viewed from above;

FIG. 8 is an example of a schematic view illustrating the arrangement of gas flow channels of the shower plate when the gas flow channels are viewed from below; and

FIG. 9 is an example of a schematic perspective view illustrating the arrangement of gas flow channels near the center of the shower plate when the gas flow channels are viewed from above.

### DETAILED DESCRIPTION

Various exemplary embodiments will be described in detail below with reference to the drawings. Note that, in the drawings, the same or corresponding parts are denoted by the same reference numerals.

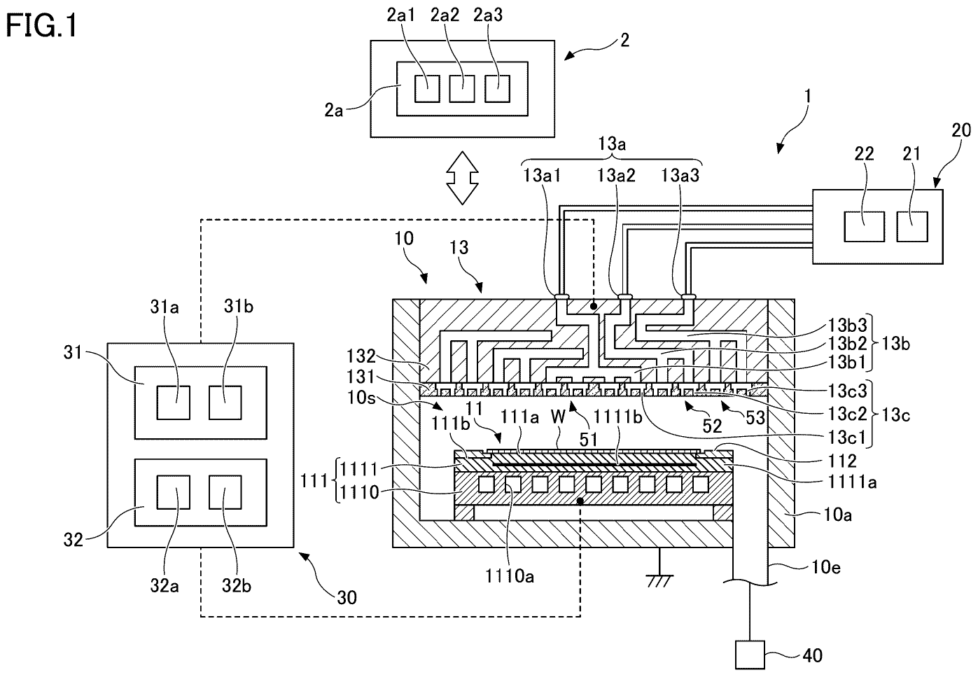

An example configuration of a plasma processing system will be described below. FIG. 1 is an example of a diagram illustrating an example configuration of a capacitively coupled substrate processing apparatus.

The plasma processing system includes a capacitively coupled substrate processing apparatus 1 and a controller 2. The capacitively coupled substrate processing apparatus 1 includes a plasma processing chamber (processing chamber) 10, a gas supply 20, a power supply 30, and an exhaust system 40. Further, the substrate processing apparatus 1 includes a substrate support 11 and a gas introduction section. The gas introduction section is configured to introduce at least one processing gas into the plasma processing chamber 10. The gas introduction section includes a showerhead 13. The substrate support 11 is disposed in the plasma processing chamber 10. The showerhead 13 is disposed above the substrate support 11. In one embodiment, the showerhead 13 constitutes at least a portion of a ceiling of the plasma processing chamber 10. The plasma processing chamber 10 includes a plasma processing space 10s defined by the showerhead 13, a side wall 10a of the plasma processing chamber 10, and the substrate support 11. The plasma processing chamber 10 includes at least one gas supply port for supplying at least one processing gas to the plasma processing space 10s, and at least one gas discharge port for discharging the gas from the plasma processing space 10s. The plasma processing chamber 10 is grounded. The showerhead 13 and the substrate support 11 are electrically isolated from a housing of the plasma processing chamber 10.

The substrate support 11 includes a body 111 and a ring assembly 112. The body 111 includes a central region 111a for supporting a substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 so as to surround the substrate W on the central region 111a of the body 111. Thus, the central region 111a is also referred to as a substrate support surface for supporting the substrate W, and the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a includes the central region 111a. In one embodiment, the ceramic member 1111a also includes the annular region 111b. Another member surrounding the electrostatic chuck 1111, such as an annular electrostatic chuck or an annular insulating member, may include the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32, which will be described later, may be disposed in the ceramic member 1111a. In this case, at least one RF/DC electrode functions as a lower electrode. In a case where a bias RF signal and/or a DC signal, which will be described later, are supplied to at least one RF/DC electrode, the RF/DC electrode is also be referred to as a bias electrode. Note that the conductive member of the base 1110 and at least one RF/DC electrode may function as a plurality of lower electrodes. Further, the electrostatic electrode 1111b may function as a lower electrode. Accordingly, the substrate support 11 includes at least one lower electrode.

The ring assembly 112 includes one or more annular members. In one embodiment, the one or more annular members include one or more edge rings and at least one cover ring. The edge rings are formed of a conductive material or an insulating material, and the cover ring is formed of an insulating material.

Further, the substrate support 11 may include a temperature adjustment module configured to adjust at least one of the electrostatic chuck 1111, the ring assembly 112, or the substrate W to a target temperature. The temperature adjustment module may include a heater, a heat transfer medium, a flow channel 1110a, or a combination thereof. A heat transfer fluid, such as brine or gas, flows through the flow channel 1110a. In one embodiment, the flow channel 1110a is formed in the base 1110, and one or more heaters are disposed in the ceramic member 1111a of the electrostatic chuck 1111. Further, the substrate support 11 may include a heat transfer gas supply configured to supply a heat transfer gas to a gap between a back surface of the substrate W and the central region 111a.

The showerhead 13 is configured to introduce at least one processing gas from the gas supply 20 into the plasma processing space 10s. The showerhead 13 includes at least one gas supply port 13a (13a1 to 13a3), at least one gas flow channel 13b (13b1 to 13b3), and a plurality of gas introduction ports 13c (13c1 to 13c3). A processing gas supplied to the gas supply port 13a is conveyed through the gas flow channel 13b and then introduced into the plasma processing space 10s via the plurality of gas introduction ports 13c.

The showerhead 13 illustrated in FIG. 1 includes a gas introduction part 51, a gas introduction part 52, and a gas introduction part 53. The gas introduction part 51 introduces a gas into a central region of the substrate W in the plasma processing chamber 10. The gas introduction part 52 introduces a gas into a region (an intermediate region) located outward of the gas introduction part 51. The gas introduction part 53 introduces a gas into a region (an edge region) located outward of the gas introduction part 52. The gas introduction part 51, the gas introduction part 52, and the gas introduction part 53 are concentrically arranged.

The gas flow channel 13b includes a gas flow channel 13b1, a gas flow channel 13b2, and a gas flow channel 13b3.

A gas supply port 13a1 and a plurality of gas introduction ports 13c1 are connected to the gas flow channel 13b1 such that a gas can flow therethrough. The gas introduction part 51 includes the gas supply port 13al, the gas flow channel 13b1, and the plurality of gas introduction ports 13c1. Further, a gas supply port 13a2 and a plurality of gas introduction ports 13c2 are connected to the gas flow channel 13b2 such that a gas can flow therethrough. The gas introduction part 52 includes the gas supply port 13a2, the gas flow channel 13b2, and the plurality of gas introduction ports 13c2. Further, a gas supply port 13a3 and a plurality of gas introduction ports 13c3 are connected to the gas flow channel 13b3 such that a gas can flow therethrough. The gas introduction part 53 includes the gas supply port 13a3, the gas flow channel 13b3, and the plurality of gas introduction ports 13c3.

Further, the showerhead 13 includes at least one upper electrode. The gas introduction section may include, in addition to the showerhead 13, one or more side gas injectors (SGIs) attached to one or more openings formed in the side wall 10a.

Further, the showerhead 13 includes an electrode plate 131 and a shower plate 132.

The electrode plate 131 is disposed to face the plasma processing space 10s. The electrode plate 131 is formed of, for example, Si, SiC, or the like. The gas introduction ports 13c (13c1 to 13c3) are formed in the electrode plate 131.

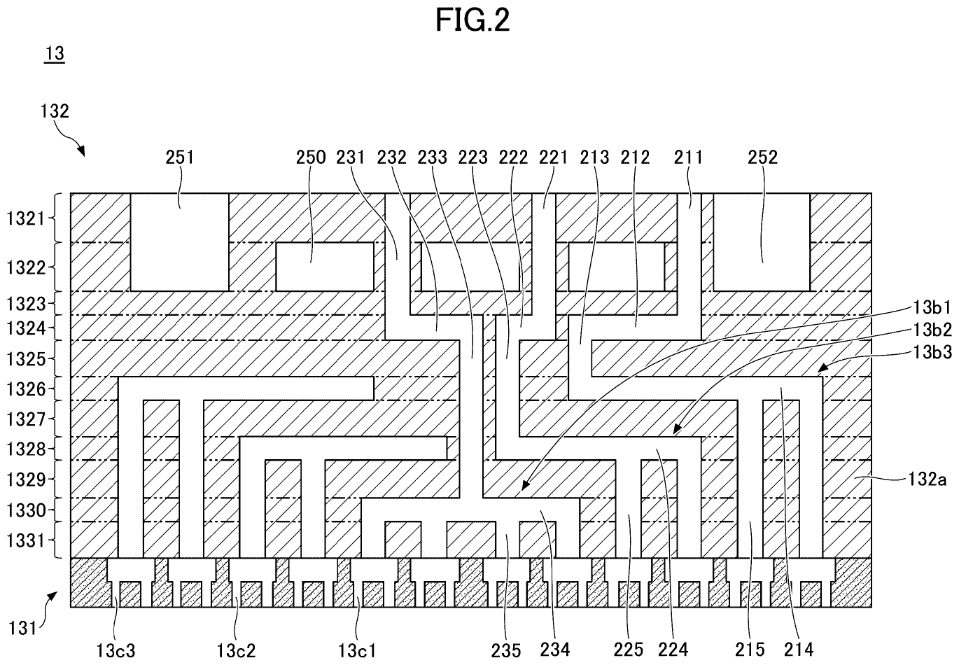

The shower plate 132 is disposed on the upper side of the electrode plate 131 and holds the electrode plate 131. The shower plate 132 includes a base 132a (see FIG. 2) formed of aluminum, an aluminum alloy, or the like, for example.

In addition, a brine flow channel 250 (a heat medium flow channel) (see FIG. 2 described later) through which a heat medium such as brine or a cooling liquid flows is formed in the base 132a of the shower plate 132. Thus, the shower plate 132 has a function for cooling the electrode plate 131 held thereon. Further, the gas flow channel 13b (including the gas flow channels 13b1 to 13b3) is formed in the base 132a of the shower plate 132. Outer surfaces and inner surfaces of the base 132a (inner walls of the gas flow channel 13b) of the shower plate 132 may be anodized in order to suppress corrosion by processing gases.

Accordingly, a gas (a third gas) supplied from the gas supply port 13a1 flows into the gas flow channel 13b1 that branches into a plurality of flow channels, and the third gas is introduced from the gas introduction ports 13c1 into the central region in the plasma processing chamber 10. Further, a gas (a second gas) supplied from the gas supply port 13a2 flows into the gas flow channel 13b2 that branches into a plurality of flow channels, and the second gas is introduced from the gas introduction ports 13c2 into the intermediate region in the plasma processing chamber 10. Further, a gas (a first gas) supplied from the gas supply port 13a3 flows into the gas flow channel 13b3 that branches into a plurality of flow channels, and the first gas is introduced from the gas introduction ports 13c3 into the edge region in the plasma processing chamber 10.

The gas flow channel 13b (including the gas flow channels 13b1 to 13b3) illustrated in FIG. 1 is schematically illustrated, and will be described later with reference to FIG. 2 and the subsequent drawings.

The gas supply 20 may include at least one gas source 21 and at least one flow controller 22. In one embodiment, the gas supply 20 is configured to supply at least one processing gas from the corresponding gas source 21 to the showerhead 13 via the corresponding flow controller 22. Each flow controller 22 may include, for example, a mass flow controller or a pressure-controlled flow controller. Further, the gas supply 20 may include one or more flow modulation devices configured to modulate or pulse the flow of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. With this configuration, plasma is formed from at least one processing gas supplied into the plasma processing space 10s. Thus, the RF power supply 31 can function as at least a part of a plasma generator configured to generate plasma from one or more processing gases in the plasma processing chamber 10. Further, by supplying the bias RF signal to at least one lower electrode, a bias potential is generated in the substrate W, and ion components in the formed plasma can be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal or the bias RF signal may be pulsed.

Further, the power supply 30 may include the DC power supply 32 coupled to the plasma processing chamber 10. The DC power supply 32 includes a first DC generator 32a and a second DC generator 32b. In one embodiment, the first DC generator 32a is connected to at least one lower electrode and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, at least one of the first DC signal or the second DC signal may be pulsed. In this case, a sequence of voltage pulses is applied to at least one lower electrode and/or at least one upper electrode. The voltage pulses may have a rectangular waveform, a trapezoidal waveform, a triangular waveform, or a combination of these pulse waveforms. In one embodiment, a waveform generator for generating a sequence of voltage pulses from a DC signal is connected between the first DC generator 32a and at least one lower electrode. Thus, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have positive polarity or negative polarity. Additionally, the sequence of voltage pulses may include one or more positive polarity voltage pulses and one or more negative polarity voltage pulses in one cycle. Note that the first and second DC generators 32a and 32b may be provided in addition to the RF power supply 31, or the first DC generator 32a may be provided instead of the second RF generator 31b.

The exhaust system 40 can be connected to a gas discharge port 10e provided at the bottom of the plasma processing chamber 10, for example. The exhaust system 40 may include a pressure regulating valve and a vacuum pump. The pressure regulating valve regulates the pressure in the plasma processing space 10s. The vacuum pump may include a turbomolecular pump, a dry pump, or a combination thereof.

The controller 2 processes computer-executable instructions that cause the substrate processing apparatus 1 to perform various processes described in the present disclosure. The controller 2 may be configured to control components of the substrate processing apparatus 1 to perform the various processes described herein. In one embodiment, a part of or the entirety of the controller 2 may be included in the substrate processing apparatus 1. The controller 2 may include a processing unit 2a1, a storage unit 2a2, and a communication interface 2a3. The controller 2 may be implemented by, for example, a computer 2a. The processing unit 2a1 may be configured to read a program from the storage unit 2a2 and execute the read program to perform various control operations. The program may be stored in the storage unit 2a2 in advance or may be acquired via a medium when necessary. The acquired program is stored in the storage unit 2a2 and is read from the storage unit 2a2 and executed by the processing unit 2al. The medium may be any of various storage media readable by the computer 2a, or may be a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the substrate processing apparatus 1 via a communication line such as a local area network (LAN).

Next, the shower plate 132 according to an embodiment will be further described with reference to FIG. 2 to FIG. 9.

FIG. 2 is an example of a schematic vertical cross-sectional view illustrating a configuration of the shower plate 132 and the electrode plate 131 according to the present embodiment.

The shower plate 132 has a multilayer structure, and includes an upper surface layer 1321, a brine flow channel layer 1322, a partition layer 1323, a pre-diffusion layer 1324, a partition layer 1325, a first diffusion layer 1326, a partition layer 1327, a second diffusion layer 1328, a partition layer 1329, a third diffusion layer 1330, and a partition layer 1331.

The base 132a of the shower plate 132 is an integrally formed body and is formed by additive manufacturing, for example. When the base 132a is formed by additive manufacturing, the gas flow channel 13b (including the gas flow channels 13b1 to 13b3) and the brine flow channel 250 are formed inside the base 132a. For additive manufacturing, a 3D printer technique or another additive manufacturing technique can be employed. Specifically, an additive manufacturing technique using a metal material can be used. For example, a manufacturing technique for forming an object by irradiating powder metal with laser or an electronic beam and sintering the powder metal, a manufacturing technique for forming an object by, while supplying powder metal or a wire, dissolving and depositing the powder metal or the wire with laser or an electronic beam, or the like can be used. However, these manufacturing techniques are merely examples, and additive manufacturing is not limited thereto. No bonding surface is formed between layers of the shower plate 132, and the base 132a of the shower plate 132 is integrally formed.

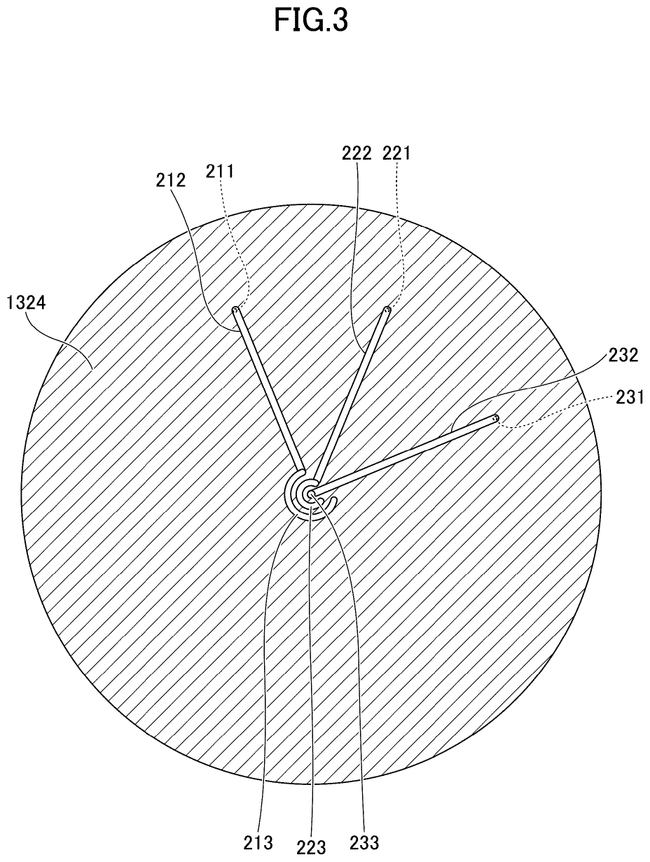

FIG. 3 is an example of a horizontal cross-sectional view of the shower plate 132 at the pre-diffusion layer 1324. Specifically, FIG. 3 is a cross-sectional view of the shower plate 132 taken along a boundary between the partition layer 1323 and the pre-diffusion layer 1324 illustrated in FIG. 2 and viewed from above. Further, flow channels 211, 221, and 231 are located on the upper side of the paper surface of FIG. 3 and thus are not visible in FIG. 3, but positions corresponding to the flow channels 211, 221, and 231 are indicated by dotted lines.

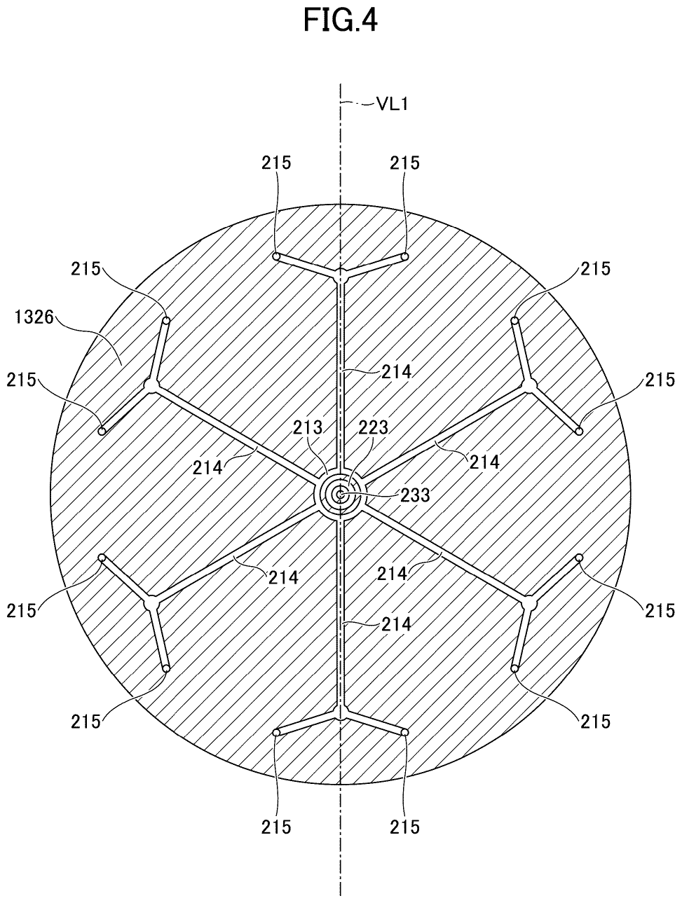

FIG. 4 is an example of a horizontal cross-sectional view of the shower plate 132 at the first diffusion layer 1326. Specifically, FIG. 4 is a cross-sectional view of the shower plate 132 taken along a boundary between the partition layer 1325 and the first diffusion layer 1326 illustrated in FIG. 2 and viewed from above.

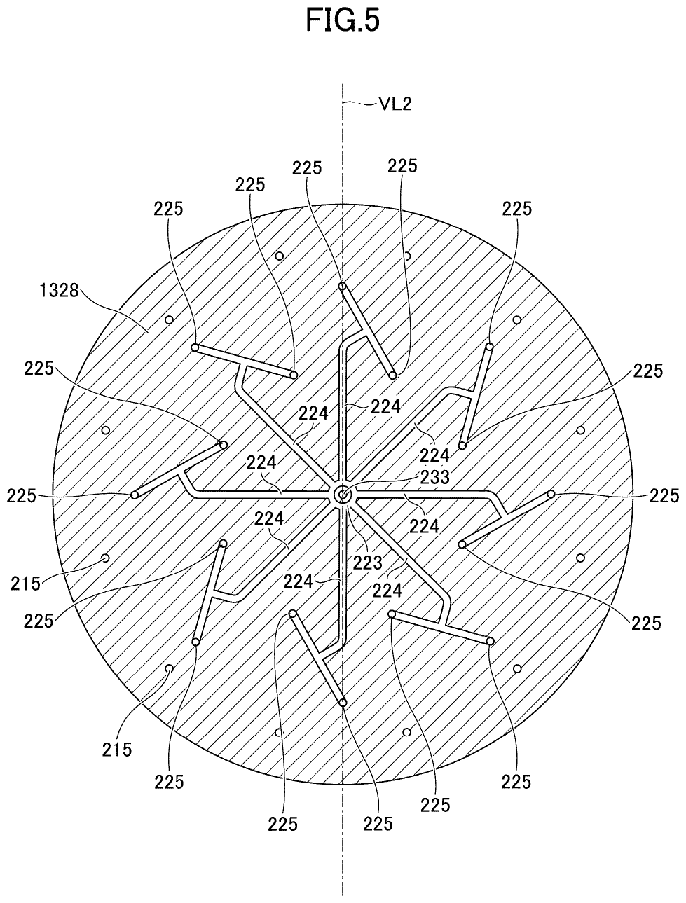

FIG. 5 is an example of a horizontal cross-sectional view of the shower plate 132 at the second diffusion layer 1328. Specifically, FIG. 5 is a cross-sectional view of the shower plate 132 taken along a boundary between the partition layer 1327 and the second diffusion layer 1328 illustrated in FIG. 2 and viewed from above.

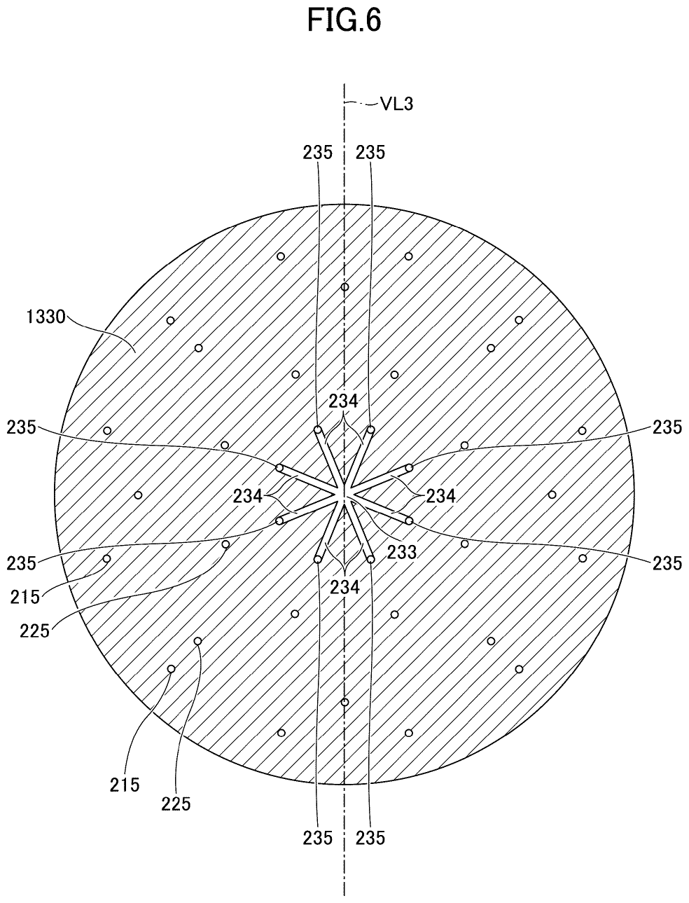

FIG. 6 is an example of a horizontal cross-sectional view of the shower plate 132 at the third diffusion layer 1330. Specifically, FIG. 6 is a cross-sectional view of the shower plate 132 taken along a boundary between the partition layer 1329 and the third diffusion layer 1330 illustrated in FIG. 2 and viewed from above.

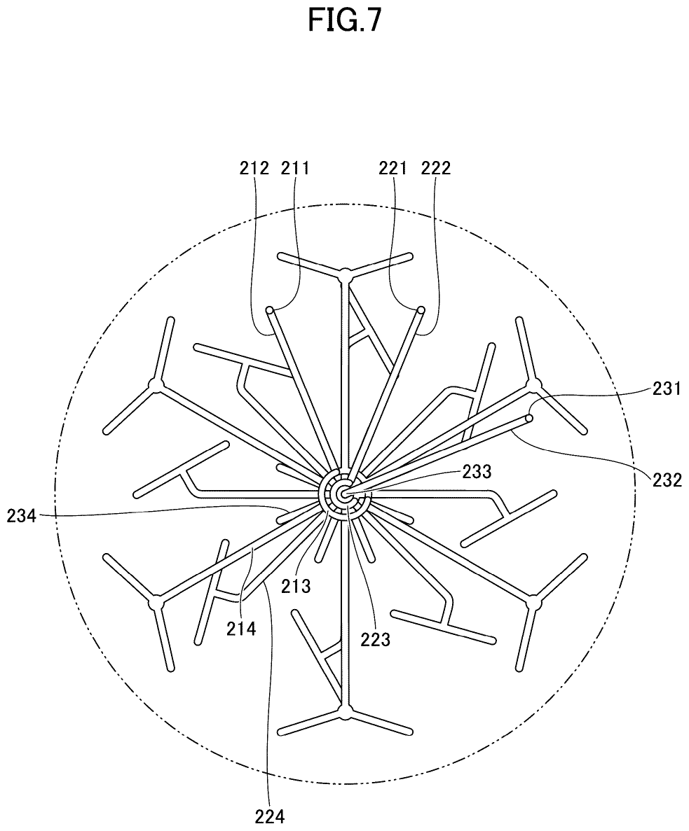

FIG. 7 is an example of a schematic view illustrating the arrangement of gas flow channels of the shower plate 132 when the gas flow channels are viewed from above. The base 132a of the shower plate 132 is indicated in a transparent manner, the outer diameter of the shower plate 132 is indicated by a two-dot dash line, and the gas flow channels 13b1 to 13b3 are indicated by solid lines.

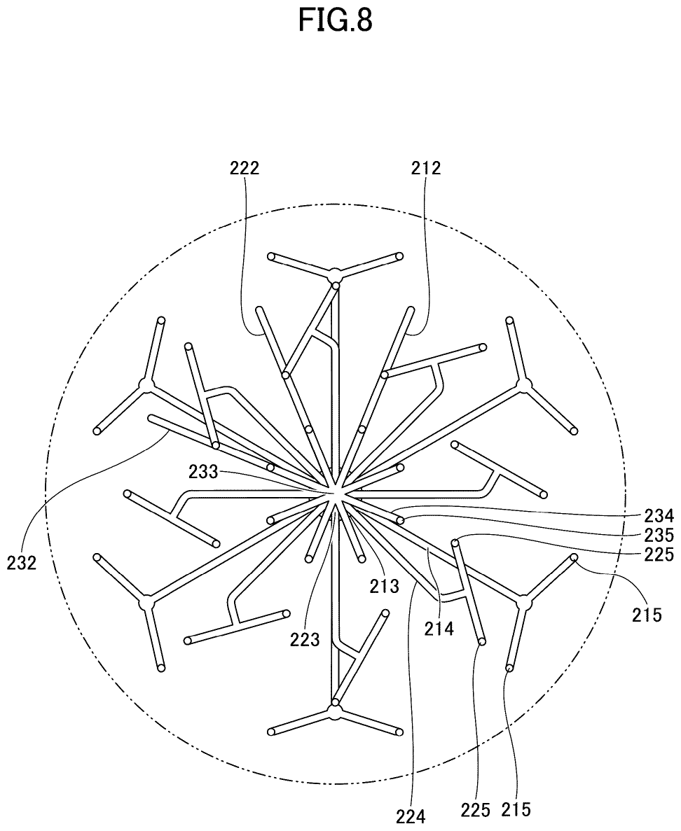

FIG. 8 is an example of a schematic view illustrating the arrangement of gas flow channels of the shower plate 132 when the gas flow channels are viewed from below. The base 132a of the shower plate 132 is indicated in a transparent manner, the outer diameter of the shower plate 132 is indicated by a two-dot dash line, and the gas flow channels 13b1 to 13b3 are indicated by solid lines.

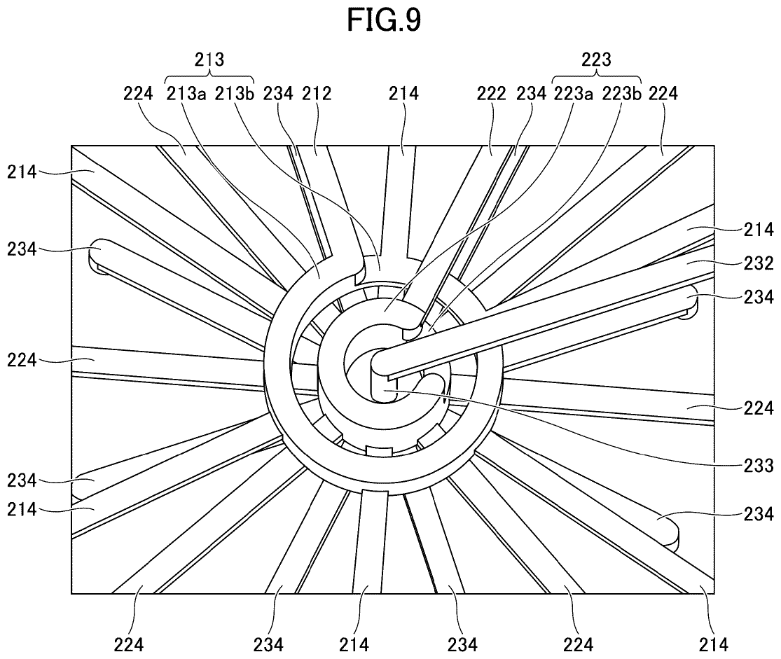

FIG. 9 is an example of a schematic perspective view illustrating the arrangement of gas flow channels near the center of the shower plate 132 when the gas flow channels are viewed from above. In FIG. 9, the base 132a of the shower plate 132 is indicated in a transparent manner, and the gas flow channels 13b1 to 13b3 are indicated by solid lines.

The shower plate 132 includes the base 132a that is an integrally formed body including the plurality of gas flow channels 13b1 to 13b3 (an example of a plurality of gas flow channels) and the brine flow channel 250 inside the base 132a.

Referring back to FIG. 2, the brine flow channel 250 through which brine (a heat medium or the like) flows is formed in the shower plate 132. A brine flow channel inlet 251 is formed at one end of the brine flow channel 250, and a brine flow channel outlet 252 is formed at the other end of the brine flow channel 250. A chiller (not illustrated) is connected to the brine flow channel inlet 251 and the brine flow channel outlet 252. Accordingly, the brine supplied from the chiller flows into the brine flow channel 250 from the brine flow channel inlet 251. The brine discharged from the brine flow channel outlet 252 is circulated to the chiller.

Further, the gas flow channels 13b1 to 13b3 are formed in the shower plate 132. The gas flow channel 13b3 for supplying the first gas into the edge region includes flow channels 211 to 215. The gas flow channel 13b2 for supplying the second gas into the intermediate region includes flow channels 221 to 225. The gas flow channel 13b1 for supplying the third gas to the central region includes flow channels 231 to 235.

First, the gas flow channel 13b3 (the flow channels 211 to 215) for supplying the first gas into the edge region will be described.

The flow channel 211 is a flow channel extending in the thickness direction (vertical direction) of the base 132a of the shower plate 132. The flow channel 211 linearly penetrates the upper surface layer 1321, the brine flow channel layer 1322, and the partition layer 1323, and communicates with the flow channel 212 formed in the pre-diffusion layer 1324.

The flow channel 212 is a flow channel formed in the pre-diffusion layer 1324 and extending in a direction (lateral direction) orthogonal to the thickness direction of the base 132a of the shower plate 132. The flow channel 212 is a flow channel that linearly connects the flow channel 211 provided on the outer peripheral side of the shower plate 132 and the flow channel 213 provided on the inner peripheral side of the shower plate 132.

The flow channel 213 (an example of a gas diffusion chamber) is a flow channel extending in the thickness direction (vertical direction) of the base 132a of the shower plate 132. As illustrated in FIG. 9, the flow channel 213 includes a flow channel 213a and a flow channel 213b. The flow channel 213a is formed in the pre-diffusion layer 1324 and the partition layer 1325, and as illustrated in FIG. 3, the flow channel 213a is formed in an arc shape obtained by cutting out a part of an annular shape when viewed from above. In the pre-diffusion layer 1324, the flow channel 221 and the flow channel 231 are arranged in the cut-out portion of the annular shape. The flow channel 213b is formed in the first diffusion layer 1326, and is formed in an annular shape when viewed from above as illustrated in FIG. 4. As described above, the flow channel 213 is formed in an annular shape, and forms the gas diffusion chamber for diffusing the gas in the circumferential direction.

The flow channel 214 (an example of a branch flow channel or a second portion) is a flow channel formed in the first diffusion layer 1326 and extending in a direction (lateral direction) orthogonal to the thickness direction of the base 132a of the shower plate 132. The gas flow channel 13b3 includes two or more flow channels 214. The flow channels 214 are flow channels that branch from the annular-shaped flow channel 213 (213b) so as to connect the flow channel 213 (213b) located at the center of the base 132a to a plurality of flow channels 215 located in the edge region. In the example illustrated in FIG. 4, a plurality of flow channels 214 extend radially in respective directions (six directions in FIG. 4), and each of the flow channels 214 further branches into a plurality of flow channels (two flow channels in FIG. 4) at the outer peripheral portion, thereby resulting in a plurality of flow channels (a total of twelve flow channels in FIG. 4). Further, the lengths of the flow channels 214 from the flow channel 213 to the plurality of flow channels 215 are equal to each other (the distances from the flow channel 213 to the plurality of flow channels 215 are the same). Further, in the example illustrated in FIG. 4, the flow channels 214 and the flow channels 215 are rotationally symmetric (six-fold rotationally symmetric).

The flow channels 215 (each of which is an example of a first portion) are flow channels extending in the thickness direction (vertical direction) of the base 132a of the shower plate 132, and linearly penetrate the partition layer 1327, the second diffusion layer 1328, the partition layer 1329, the third diffusion layer 1330, and the partition layer 1331. Further, as illustrated in FIG. 4, the plurality of flow channels 215 belonging to the gas flow channel 13b3 are symmetrical about an imaginary straight line VL1 passing through the center of the base 132a in a plan view of the base 132a of the shower plate 132. In other words, the plurality of flow channels 215 belonging to the gas flow channel 13b3 are arranged at equal intervals along a circumference.

With such a configuration, the first gas supplied from the gas supply port 13a3 (see FIG. 1) flows through the flow channels 211 to 213, branches into the plurality of flow channels 214 (each of which is an example of the branch flow channel or the second portion), flows through the plurality of flow channels 215, and is introduced into the edge region in the plasma processing chamber 10 from the gas introduction ports 13c3. The lengths from the inlet of the flow channel 211 to the outlets of the plurality of flow channels 215 are equal to each other.

Next, the gas flow channel 13b2 (the flow channels 221 to 225) for supplying the second gas to the intermediate region will be described.

The flow channel 221 is a flow channel extending in the thickness direction (vertical direction) of the base 132a of the shower plate 132. The flow channel 221 linearly penetrates the upper surface layer 1321, the brine flow channel layer 1322, and the partition layer 1323, and communicates with the flow channel 222 formed in the pre-diffusion layer 1324.

The flow channel 222 is a flow channel formed in the pre-diffusion layer 1324 and extending in a direction (lateral direction) orthogonal to the thickness direction of the base 132a of the shower plate 132. The flow channel 222 is a flow channel that linearly connects the flow channel 221 provided on the outer peripheral side of the shower plate 132 and the flow channel 223 provided on the inner peripheral side of the shower plate 132.

The flow channel 223 (an example of a gas diffusion chamber) is a flow channel extending in the thickness direction (vertical direction) of the base 132a of the shower plate 132. As illustrated in FIG. 9, the flow channel 223 includes a flow channel 223a and a flow channel 223b. The flow channel 223a is formed in the pre-diffusion layer 1324 and the partition layer 1325, and as illustrated in FIG. 3, the flow channel 223a is formed in an arc shape obtained by cutting out a part of an annular shape when viewed from above. In the pre-diffusion layer 1324, the flow channel 231 is disposed in the cut-out portion of the annular shape. The flow channel 223b is formed in the first diffusion layer 1326, the partition layer 1327, and the second diffusion layer 1328, and as illustrated in FIG. 5, the flow channel 223b is formed in an annular shape when viewed from above. As described above, the flow channel 223 is formed in an annular shape, and forms the gas diffusion chamber for diffusing the gas in the circumferential direction.

The flow channel 224 (an example of a branch flow channel or a second portion) is a flow channel formed in the second diffusion layer 1328 and extending in a direction (lateral direction) orthogonal to the thickness direction of the base 132a of the shower plate 132. The gas flow channel 13b2 includes two or more flow channels 224. The flow channels 224 are flow channels that branch from the annular-shaped flow channel 223 (223b) so as to connect the flow channel 223 (223b) located at the center of the base 132a to a plurality of flow channels 225 located in the intermediate region. In the example illustrated in FIG. 5, a plurality of flow channels 224 extend radially in respective directions (eight directions in FIG. 5), and each of the flow channels 225 further branches into a plurality of flow channels (two flow channels in FIG. 5) at the outer peripheral portion, thereby resulting in a plurality of flow channels (a total of sixteen flow channels in FIG. 5). Further, the lengths of the flow channels 224 from the flow channel 223 to the plurality of flow channels 225 are equal to each other (the distances from the flow channel 223 to the plurality of flow channels 225 are the same). Further, in the example illustrated in FIG. 5, the flow channels 224 and the flow channels 225 are rotationally symmetric (eight-fold rotationally symmetric).

The flow channels 225 (each of which is an example of a first portion) are flow channels extending in the thickness direction (vertical direction) of the base 132a of the shower plate 132, and linearly penetrate the partition layer 1329, the third diffusion layer 1330, and the partition layer 1331. Further, as illustrated in FIG. 5, the plurality of flow channels 225 belonging to the gas flow channel 13b2 are symmetrical about an imaginary straight line VL2 passing through the center of the base 132a in a plan view of the base 132a of the shower plate 132. In other words, the plurality of flow channels 225 belonging to the gas flow channel 13b2 are arranged at equal intervals along two circumferences.

With such a configuration, the second gas supplied from the gas supply port 13a2 (see FIG. 1) flows through the flow channels 221 to 223, branches into the plurality of flow channels 224 (each of which is an example of the branch flow channel or the second portion), flows through the plurality of flow channels 225, and is introduced into the intermediate region in the plasma processing chamber 10 from the gas introduction ports 13c2. The lengths from the inlet of the flow channel 221 to the outlets of the plurality of flow channels 225 are equal to each other.

Next, the gas flow channel 13b1 (the flow channels 231 to 235) for supplying the third gas to the central region will be described.

The flow channel 231 is a flow channel extending in the thickness direction (vertical direction) of the base 132a of the shower plate 132. The flow channel 231 linearly penetrates the upper surface layer 1321, the brine flow channel layer 1322, and the partition layer 1323, and communicates with the flow channel 232 formed in the pre-diffusion layer 1324.

The flow channel 232 is a flow channel formed in the pre-diffusion layer 1324 and extending in a direction (lateral direction) orthogonal to the thickness direction of the base 132a of the shower plate 132. The flow channel 232 is a flow channel that linearly connects the flow channel 231 provided on the outer peripheral side of the shower plate 132 and the flow channel 233 provided on the inner peripheral side of the shower plate 132.

The flow channel 233 (an example of a gas diffusion chamber) is a flow channel extending in the thickness direction (vertical direction) of the base 132a of the shower plate 132. As illustrated in FIG. 9, the flow channel 233 is formed in a cylindrical shape. The flow channel 233 penetrates the pre-diffusion layer 1324, the partition layer 1325, the first diffusion layer 1326, the partition layer 1327, the second diffusion layer 1328, and the partition layer 1329, and communicates with the flow channel 234 formed in the third diffusion layer 1330. Further, the flow channel 233 is formed in a cylindrical shape, and forms the gas diffusion chamber for diffusing the gas in the circumferential direction.

The flow channel 234 (an example of a branch flow channel or a second portion) is a flow channel formed in the third diffusion layer 1330 and extending in a direction (lateral direction) orthogonal to the thickness direction of the base 132a of the shower plate 132. The gas flow channel 13b1 includes two or more flow channels 234. The flow channels 234 are flow channels that branch from the cylindrical-shaped flow channel 233 so as to connect the flow channel 233 located at the center of the base 132a to a plurality of flow channels 235 located in the central region. In the example illustrated in FIG. 6, a plurality of flow channels 234 extend radially in respective directions (eight directions in FIG. 6), thereby resulting in a plurality of flow channels (eight flow channels in FIG. 6). Further, the lengths of the flow channels 234 from the flow channel 233 to the plurality of flow channels 235 are equal to each other (the distances from the flow channel 233 to the plurality of flow channels 235 are the same). Further, in the example illustrated in FIG. 6, the flow channels 234 and the flow channels 235 are rotationally symmetric (eight-fold rotationally symmetric).

The flow channels 235 (each of which is an example of a first portion) are flow channels extending in the thickness direction (vertical direction) of the base 132a of the shower plate 132, and linearly penetrate the partition layer 1331. Further, as illustrated in FIG. 6, the plurality of flow channels 235 belonging to the gas flow channel 13b1 are symmetrical about an imaginary straight line VL3 passing through the center of the base 132a in a plan view of the base 132a of the shower plate 132. In other words, the plurality of flow channels 235 belonging to the gas flow channel 13b1 are arranged at equal intervals along a circumference.

With such a configuration, the third gas supplied from the gas supply port 13a1 (see FIG. 1) flows through the flow channels 231 to 233, branches into the plurality of flow channels 234 (each of which is an example of the branch flow channel or the second portion), flows through the plurality of flow channels 235, and is introduced into the central region in the plasma processing chamber 10 from the gas introduction ports 13cl. The lengths from the inlet of the flow channel 231 to the outlets of the plurality of flow channels 235 are equal to each other.

As described above, in the shower plate 132, the flow channels 214 (each of which is an example of the branch flow channel or the second portion) for branching the first gas are formed in the first diffusion layer 1326, the flow channels 224 (each of which is an example of the branch flow channel or the second portion) for branching the second gas are formed in the second diffusion layer 1328, and the flow channels 234 (each of which is an example of the branch flow channel or the second portion) for branching the third gas are formed in the third diffusion layer 1330. That is, the branch flow channels are arranged at different positions in the thickness direction of the shower plate 132 for each gas.

Accordingly, the flow channels 214 for branching the first gas can be freely arranged without being affected by the arrangement of the flow channels 224 and 234. Therefore, the flow channels 214 extending from the flow channel 213 to the plurality of flow channels 215 can be formed with fewer bends. In addition, by forming the flow channels 214 with fewer bends and forming each of the flow channels 214 into a shape defined by one or more straight lines, it is possible to reduce the lengths of the flow channels 214 from the flow channel 213 to the plurality of flow channels 215. Further, the volume of the entire gas flow channel 13b3 (flow channels 211 to 215) can be reduced.

Similarly, the flow channels 224 for branching the second gas can be freely arranged without being affected by the arrangement of the flow channels 214 and 234. Therefore, the flow channels 224 extending from the flow channel 223 to the plurality of flow channels 225 can be formed with fewer bends. In addition, by forming the flow channels 224 with fewer bends and forming each of the flow channels 224 into a shape defined by one or more straight lines, it is possible to reduce the lengths of the flow channels 224 from the flow channel 223 to the plurality of flow channels 225. Further, the volume of the entire gas flow channel 13b2 (flow channels 221 to 225) can be reduced.

Similarly, the flow channels 234 for branching the third gas can be freely arranged without being affected by the arrangement of the flow channels 214 and 224. Therefore, the flow channels 234 extending from the flow channel 233 to the plurality of flow channels 235 can be formed with fewer bends. In addition, by forming the flow channels 234 with fewer bends and forming each of the flow channels 234 into a shape defined by one or more straight lines, it is possible to reduce the lengths of the flow channels 234 from the flow channel 233 to the plurality of flow channels 235. Further, the volume of the entire gas flow channel 13b1 (flow channels 231 to 235) can be reduced.

Further, by reducing the volumes of the gas flow channels 13b1 to 13b3, it is possible to improve the responsiveness in the case of switching between supply and stop of the gases. Further, the amount of gases remaining in the gas flow channels 13b1 to 13b3 can be reduced. In addition, an influence of the remaining gases on a substrate processing process can be suppressed

Further, the flow channels 214 connected to the flow channels 215 arranged in the edge region are positioned higher than the flow channels 224 connected to the flow channels 225 arranged in the intermediate region. Further, the flow channels 224 connected to the flow channels 225 arranged in the intermediate region are positioned higher than the flow channels 234 connected to the flow channels 235 arranged in the central region. That is, a distribution flow channel for supplying gas into a radially outward region of the shower plate 132 is formed at a position higher than a distribution flow channel for supplying gas into a radially inward region of the shower plate 132.

Accordingly, the flow channels 214 can be freely arranged without being affected by the arrangement of the flow channels 225 and the flow channels 235, and the lengths of the flow channels 214 can be reduced. Further, the flow channels 224 can be freely arranged without being affected by the arrangement of the flow channels 215 and the flow channels 235, and the lengths of the flow channels 224 can be reduced. Further, the flow channels 234 can be freely arranged without being affected by the arrangement of the flow channels 215 and the flow channels 225, and the lengths of the flow channels 234 can be reduced.

Further, as illustrated in FIG. 7 and FIG. 8, the cylindrical-shaped flow channel 233, the annular-shaped flow channel 223 (223b), and the annular-shaped flow channel 213 (213b) are concentrically arranged when viewed from above or below. Further, among the flow channels 233, 223, and 213, a flow channel for supplying a gas into a radially outward region of the shower plate 132 is formed radially outward of a flow channel for supplying a gas into a radially inner region of the shower plate 132. That is, the annular-shaped flow channel 213 (213b) is formed radially outward of the annular-shaped flow channel 223 (223b). Further, the annular-shaped flow channel 223 (223b) is formed radially outward of the cylindrical-shaped flow channel 233.

Accordingly, the flow channels 214 can be freely arranged without being affected by the arrangement of the flow channel 223 and the flow channel 233, and the lengths of the flow channels 214 can be reduced. Further, the flow channels 224 can be freely arranged without being affected by the arrangement of the flow channel 213 and the flow channel 233, and the lengths of the flow channels 224 can be reduced. The flow channels 234 can be freely arranged without being affected by the arrangement of the flow channel 213 and the flow channel 223, and the lengths of the flow channels 234 can be reduced.

Further, the base 132a of the shower plate 132 is preferably integrally formed by additive manufacturing.

Accordingly, for example, the need for pressurization or the like in diffusion bonding can be eliminated, for example, and each layer can be formed so as to have any thickness. That is, the thickness of the shower plate 132 can be reduced. This makes it possible to reduce the lengths of flow channels in the thickness direction of the shower plate 132.

Alternatively, the thickness of the brine flow channel layer 1322 can be increased by reducing the thickness from the partition layer 1323 to the partition layer 1331 while maintaining the thickness of the shower plate 132. This increases the cross-sectional area of the brine flow channel 250, thereby improving the performance of cooling the electrode plate 131 by the shower plate 132.

Further, an example in which outer surfaces and inner surfaces of the base 132a in which the gas flow channel 13b and the brine flow channel 250 are formed are anodized has been described above; however, the present disclosure is not limited thereto. The shower plate 132 may be integrally formed by additive manufacturing of two materials. For example, a material of a plurality of wall portions of the gas flow channels 13b1 to 13b3 and a material of the other portion (main body portion) connecting the plurality of wall portions may be different from each other. In other words, the base 132a of the shower plate 132 may be formed of a first material, and the wall portions of the gas flow channels 13b1 to 13b3 may be formed of a second material different from the first material. As the first material, a material (for example, aluminum (Al), tungsten (W), or molybdenum (Mo)) having a higher thermal conductivity than the second material is used. As the second material, a material (for example, stainless steel (SUS: steel use stainless as referred to in the Japanese Industrial Standards), WOₓ (x is a real number), MoO_{y} (y is a real number), titanium (Ti), platinum (Pt), Hastelloy (registered trademark), or the like) having higher corrosion resistance or the like to processing gases than the first material is used. Accordingly, corrosion of the wall portions of the gas flow channels 13b1 to 13b3 by the processing gases can be suppressed, and the thermal conductivity of the shower plate 132 can be secured. In addition, the wall portions of the gas flow channel 13b1 to 13b3 need not be anodized.

Further, an example in which the shower plate 132 is partitioned into three regions, that is, the central region, the intermediate region, and the edge region, and a gas is supplied to each region has been described above; however, the number of regions is not limited to three and may be two or four or more.

An example in which the substrate processing apparatus 1 including the shower plate 132 according to the present embodiment is a plasma processing apparatus that generates plasma in the plasma processing chamber 10 has been described above; however, the present disclosure is not limited thereto. The shower plate 132 may be applied to a substrate processing apparatus such as a thermal chemical vapor deposition (CVD) apparatus.

Although embodiments and the like of the plasma processing system have been described above, the present disclosure is not limited to the above-described embodiments, and various modifications and improvements can be made within the scope of the gist of the present disclosure described in the claims.

The above-described embodiments include, for example, the following aspects.

### (Clause 1)

A shower plate including:
a base that is an integrally formed body including a plurality of gas flow channels therein, wherein
each of the plurality of gas flow channels includes
   a first portion extending in a thickness direction of the base, and
   a second portion communicating with the first portion and extending in a direction orthogonal to the thickness direction, and
second portions belonging to different gas flow channels of the plurality of gas flow channels are arranged at mutually different positions in the thickness direction.

### (Clause 2)

The shower plate according to clause 1, wherein a second portion belonging to one gas flow channel of the plurality of gas flow channels is a branch flow channel communicating with a plurality of first portions belonging to the one gas flow channel.

### (Clause 3)

The shower plate according to clause 1 or 2, wherein a plurality of second portions belonging to one gas flow channel of the plurality of gas flow channels are symmetrical about an imaginary straight line passing through a center of the base in a plan view of the base.

### (Clause 4)

The shower plate according to any one of clauses 1 to 3, wherein
one gas flow channel of the plurality of gas flow channels includes two or more second portions,
the two or more second portions branch from a gas diffusion chamber belonging to the one gas flow channel and located at a center of the base, so as to couple the gas diffusion chamber to a plurality of first portions belonging to the one gas flow channel, and
lengths of the two or more second portions branching from the gas diffusion chamber are equal to each other.

### (Clause 5)

The shower plate according to any one of clauses 1 to 4, wherein
one gas flow channel of the plurality of gas flow channels includes two or more second portions, and
the two or more second portions branch radially from a gas diffusion chamber belonging to the one gas flow channel and located at a center of the base, so as to couple the gas diffusion chamber to a plurality of first portions belonging to the one gas flow channel.

### (Clause 6)

The shower plate according to any one of clauses 1 to 4, wherein
one gas flow channel of the plurality of gas flow channels includes two or more second portions, and
the two or more second portions branch radially from a gas diffusion chamber belonging to the one gas flow channel and located at a center of the base, so as to couple the gas diffusion chamber to a plurality of first portions belonging to the one gas flow channel, and each of the two or more second portions further branches into a plurality of gas flow channels at a peripheral portion thereof.

### (Clause 7)

The shower plate according to any one of clauses 1 to 6, wherein,
the plurality of gas flow channels include a first gas flow channel and a second gas flow channel,
a second portion of the first gas flow channel is positioned higher than a second portion of the second gas flow channel in the thickness direction,
the first gas flow channel includes two or more second portions,
the two or more second portions belonging to the first gas flow channel branch from a gas diffusion chamber belonging to the first gas flow channel and located at a center of the base, so as to couple the gas diffusion chamber belonging to the first gas flow channel to a plurality of first portions belonging to the first gas flow channel,
the second gas flow channel includes two or more second portions,
the two or more second portions belonging to the second gas flow channel branch from a gas diffusion chamber belonging to the second gas flow channel and located at the center of the base, so as to couple the gas diffusion chamber belonging to the second gas flow channel to a plurality of first portions belonging to the second gas flow channel, and
a length of each of the two or more second portions branching from the gas diffusion chamber belonging to the first gas flow channel is greater than a length of each of the two or more second portions branching from the gas diffusion chamber belonging to the second gas flow channel.

### (Clause 8)

The shower plate according to any one of clauses 1 to 6, wherein,
the plurality of gas flow channels include a first gas flow channel and a second gas flow channel,
a second portion of the first gas flow channel is positioned higher than a second portion of the second gas flow channel in the thickness direction,
the first gas flow channel includes two or more second portions,
the two or more second portions belonging to the first gas flow channel branch from a gas diffusion chamber belonging to the first gas flow channel and located at a center of the base, so as to couple the gas diffusion chamber belonging to the first gas flow channel to a plurality of first portions belonging to the first gas flow channel,
the second gas flow channel includes two or more second portions,
the two or more second portions belonging to the second gas flow channel branch from a gas diffusion chamber belonging to the second gas flow channel and located at the center of the base, so as to couple the gas diffusion chamber belonging to the second gas flow channel to a plurality of first portions belonging to the second gas flow channel, and
a region in which the plurality of first portions belonging to the first gas flow channel are arranged is located outward of a region in which the plurality of first portions belonging the second gas flow channel are arranged.

### (Clause 9)

The shower plate according to clause 7 or 8, wherein the gas diffusion chamber belonging to the first gas flow channel has an annular shape in a plan view of the base and is located outward of the gas diffusion chamber belonging to the second gas flow channel.

### (Clause 10)

The shower plate according to any one of clauses 1 to 9, wherein the base is formed by additive manufacturing.

### (Clause 11)

The shower plate according to clause 10, wherein
the base includes a first material, and
a wall portion of each of the plurality of gas flow channels includes a second material different from the first material.

### (Clause 12)

The shower plate according to clause 11, wherein
the first material has a higher thermal conductivity than the second material, and
the second material has higher corrosion resistance to gas than the first material.

### (Clause 13)

The shower plate according to clause 12, wherein
the first material is aluminum (Al), tungsten (W), or molybdenum (Mo), and
the second material is stainless steel, WOₓ (x is a real number), MoO_{y} (y is a real number), titanium (Ti), platinum (Pt), or Hastelloy (registered trademark).

### (Clause 14)

The shower plate according to any one of clauses 1 to 9, wherein the base includes a heat medium flow channel through which a heat medium flows.

### (Clause 15)

A substrate processing apparatus including:
the shower plate of any one of clauses 1 to 14.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

According to one aspect of the present disclosure, a shower plate and a substrate processing apparatus that can reduce the length of a gas flow channel can be provided.

What is claimed is:

1. A shower plate comprising:
a base that is an integrally formed body including a plurality of gas flow channels therein, wherein
each of the plurality of gas flow channels includes
a first portion extending in a thickness direction of the base, and
a second portion communicating with the first portion and extending in a direction orthogonal to the thickness direction, and
second portions belonging to different gas flow channels of the plurality of gas flow channels are arranged at mutually different positions in the thickness direction.

2. The shower plate according to claim 1, wherein a second portion belonging to one gas flow channel of the plurality of gas flow channels is a branch flow channel communicating with a plurality of first portions belonging to the one gas flow channel.

3. The shower plate according to claim 1, wherein a plurality of second portions belonging to one gas flow channel of the plurality of gas flow channels are symmetrical about an imaginary straight line passing through a center of the base in a plan view of the base.

4. The shower plate according to claim 1, wherein
one gas flow channel of the plurality of gas flow channels includes two or more second portions,
the two or more second portions branch from a gas diffusion chamber belonging to the one gas flow channel and located at a center of the base, so as to couple the gas diffusion chamber to a plurality of first portions belonging to the one gas flow channel, and
lengths of the two or more second portions branching from the gas diffusion chamber are equal to each other.

5. The shower plate according to claim 1, wherein
one gas flow channel of the plurality of gas flow channels includes two or more second portions, and
the two or more second portions branch radially from a gas diffusion chamber belonging to the one gas flow channel and located at a center of the base, so as to couple the gas diffusion chamber to a plurality of first portions belonging to the one gas flow channel.

6. The shower plate according to claim 1, wherein
one gas flow channel of the plurality of gas flow channels includes two or more second portions, and
the two or more second portions branch radially from a gas diffusion chamber belonging to the one gas flow channel and located at a center of the base, so as to couple the gas diffusion chamber to a plurality of first portions belonging to the one gas flow channel, and each of the two or more second portions further branches into a plurality of gas flow channels at a peripheral portion thereof.

7. The shower plate according to claim 1, wherein,
the plurality of gas flow channels include a first gas flow channel and a second gas flow channel,
a second portion of the first gas flow channel is positioned higher than a second portion of the second gas flow channel in the thickness direction,
the first gas flow channel includes two or more second portions,
the two or more second portions belonging to the first gas flow channel branch from a gas diffusion chamber belonging to the first gas flow channel and located at a center of the base, so as to couple the gas diffusion chamber belonging to the first gas flow channel to a plurality of first portions belonging to the first gas flow channel,
the second gas flow channel includes two or more second portions,
the two or more second portions belonging to the second gas flow channel branch from a gas diffusion chamber belonging to the second gas flow channel and located at the center of the base, so as to couple the gas diffusion chamber belonging to the second gas flow channel to a plurality of first portions belonging to the second gas flow channel, and
a length of each of the two or more second portions branching from the gas diffusion chamber belonging to the first gas flow channel is greater than a length of each of the two or more second portions branching from the gas diffusion chamber belonging to the second gas flow channel.

8. The shower plate according to claim 1, wherein,
the plurality of gas flow channels include a first gas flow channel and a second gas flow channel,
a second portion of the first gas flow channel is positioned higher than a second portion of the second gas flow channel in the thickness direction,
the first gas flow channel includes two or more second portions,
the two or more second portions belonging to the first gas flow channel branch from a gas diffusion chamber belonging to the first gas flow channel and located at a center of the base, so as to couple the gas diffusion chamber belonging to the first gas flow channel to a plurality of first portions belonging to the first gas flow channel,
the second gas flow channel includes two or more second portions,
the two or more second portions belonging to the second gas flow channel branch from a gas diffusion chamber belonging to the second gas flow channel and located at the center of the base, so as to couple the gas diffusion chamber belonging to the second gas flow channel to a plurality of first portions belonging to the second gas flow channel, and
a region in which the plurality of first portions belonging to the first gas flow channel are arranged is located outward of a region in which the plurality of first portions belonging to the second gas flow channel are arranged.

9. The shower plate according to claim 7, wherein the gas diffusion chamber belonging to the first gas flow channel has an annular shape in a plan view of the base and is located outward of the gas diffusion chamber belonging to the second gas flow channel.

10. The shower plate according to claim 1, wherein the base is formed by additive manufacturing.

11. The shower plate according to claim 10, wherein
the base includes a first material, and
a wall portion of each of the plurality of gas flow channels includes a second material different from the first material.

12. The shower plate according to claim 11, wherein
the first material has a higher thermal conductivity than the second material, and
the second material has higher corrosion resistance to gas than the first material.

13. The shower plate according to claim 12, wherein
the first material is aluminum (Al), tungsten (W), or molybdenum (Mo), and
the second material is stainless steel, WOₓ (x is a real number), MoO_{y} (y is a real number), titanium (Ti), platinum (Pt), or Hastelloy (registered trademark).

14. The shower plate according to claim 1, wherein the base includes a heat medium flow channel through which a heat medium flows.

15. A substrate processing apparatus comprising:
the shower plate of claim 1.
